(19) United States
(12) Patent Application Publication
(10) Pub. No.: US 2026/0064927 A1
(43) Pub. Date: Mar. 5, 2026

(54) MITIGATING DYNAMIC IR

(71) Applicant: MEDIATEK INC., Hsinchu City (TW)

(72) Inventor: Heerak BANDOPADHYAY, Bengaluru (IN)

(21) Appl. No.: 19/089,490

(22) Filed: Mar. 25, 2025

(30) Foreign Application Priority Data
Aug. 27, 2024 (IN) 202421064783

(51) Int. Cl. G06F 30/367

(52) U.S. Cl. CPC G06F 30/367

(57) ABSTRACT

In an aspect of the disclosure, a method and an apparatus is provided. The apparatus may include one or more computing devices. The one or more computing devices identify a dynamically IR impacted cell in an integrated circuit. The one or more computing devices replace the identified dynamically IR impacted cell with a modified cell having a port. The one or more computing devices couple the port of the modified cell to a dedicated net configured to supply or sink charge. In another aspect of the disclosure, an integrated circuit is also provided. The integrated circuit includes a dedicated net, a modified standard cell including a port, a transistor coupled between the port and the dedicated net. The dedicated net is configured as a charge storage network that supplies or sinks charge to mitigate dynamic IR drop within the modified standard cell.

### CROSS-REFERENCE TO RELATED APPLICATION(S)

The present invention is a non-Provisional Application of and claims priority to Indian Provisional Patent Application No. 202421064783, filed on Aug. 27, 2024. The Indian Provisional Patent Applications are hereby incorporated by reference in their entireties

### BACKGROUND

### Field

The present disclosure relates generally to integrated circuits, and more particularly, to techniques of mitigating dynamic IR drop in integrated circuits.

### Background

The statements in this section merely provide background information related to the present disclosure and may not constitute prior art.

In modern integrated circuits (ICs), stable power delivery needs to be maintained for reliable operation. As semiconductor technologies advance and circuit densities increase, power distribution networks face growing challenges in delivering consistent voltage levels across the chip. One significant challenge is voltage drop, commonly known as IR drop, which occurs due to the resistance in power delivery networks and the current drawn by circuit elements.

IR drop manifests in two primary forms: static and dynamic. Static IR drop relates to the average current consumption of the circuit and primarily affects the overall robustness of the power grid. It determines whether the power distribution network can adequately support the chip's average power requirements. Dynamic IR drop, on the other hand, is a transient phenomenon caused by instantaneous current demands when multiple circuit elements switch simultaneously or in rapid succession. This type of voltage drop is particularly challenging because it can cause localized timing violations and functional failures, especially in high-performance designs operating at elevated frequencies.

In one approach, decoupling capacitors (DECAPs) are used to manage dynamic IR drop. These DECAP cells function as local charge reservoirs, providing temporary current during periods of high demand and helping to stabilize voltage levels. Designers may place DECAP cells near circuit elements that are susceptible to dynamic IR drop. However, this approach faces limitations in modern designs where available chip area is increasingly constrained, making it difficult to place sufficient DECAP cells in optimal locations.

### SUMMARY

The following presents a simplified summary of one or more aspects in order to provide a basic understanding of such aspects. This summary is not an extensive overview of all contemplated aspects, and is intended to neither identify key or critical elements of all aspects nor delineate the scope of any or all aspects. Its sole purpose is to present some concepts of one or more aspects in a simplified form as a prelude to the more detailed description that is presented later.

In an aspect of the disclosure, a method and an apparatus is provided. The apparatus may include one or more computing devices. The one or more computing devices identify a dynamically IR impacted cell in an integrated circuit. The one or more computing devices replace the identified dynamically IR impacted cell with a modified cell having a port. The one or more computing devices couple the port of the modified cell to a dedicated net configured to supply or sink charge. In another aspect of the disclosure, an integrated circuit is also provided. The integrated circuit includes a dedicated net, a modified standard cell including a port, a transistor coupled between the port and the dedicated net. The dedicated net is configured as a charge storage network that supplies or sinks charge to mitigate dynamic IR drop within the modified standard cell.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

FIG. 1 illustrates a flow chart illustrating a typical hierarchical design process of an integrated circuit (IC);

FIG. 2 illustrates a method for analyzing IR drop of an IC.

FIG. 3 is an example illustration of the layout of an IC; and

FIG. 4 is a block diagram illustrating example physical components of a computer system.

FIG. 5 is an example illustration of voltage droop and ground bounce.

FIG. 6 is a diagram illustrating using decoupling capacitor cells and non-toggling instances to address dynamic IR drop in integrated circuits.

FIG. 7(A) is a diagram illustrating a non-toggling instance that acts as a local charge reservoir to mitigate dynamic IR drop in a nearby impacted cell.

FIG. 7(B) is a diagram illustrating a transistor-level view of a non-toggling instance.

FIG. 8(A) is a diagram illustrating the integration of an additional port into a dynamic IR impacted cell, enabling it to draw supplemental charge from a dedicated power network.

FIG. 8(B) is a diagram illustrating the integration of an additional port into a dynamic IR impacted cell, enabling it to establish an alternate ground path to address ground-related dynamic IR issues.

FIG. 8(C) is a diagram illustrating a layout scenario where a dynamic IR impacted cell with an added port is connected to a dedicated net.

FIG. 9 illustrates a flow chart of a process for mitigating dynamic IR.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts.

The development process for integrated circuits (ICs) such as super larger scale integrated circuits (LSIs) has generally employed computer assisted design (CAD). According to this CAD-based development process, abstract circuit data, which corresponds to the functions of an integrated circuit to be developed, is defined by using so-called hardware description language (HDL), and the defined circuit is used to form a concrete circuit structure to be mounted on a chip.

The design cycle of an IC (also known as a chip) refers to a process from the initiation of the chip design to its completion. Typically, the chip design cycle includes the following steps:
Planning and Design: Similar to the initial planning in architectural design, the engineering team determines the chip's functions, performance indicators, and architecture design during this stage.
RTL Design (Register-Transfer Level Design): During the RTL design phase, engineers use hardware description languages (HDLs) such as Verilog or VHDL to write high-level logical descriptions, defining the chip's logical functions and data transmission.
Synthesis and Optimization: Software tools convert RTL descriptions into logic gate-level circuits and optimize them to meet performance, power consumption, and area (PPA) requirements.
Layout Design: Engineers design the physical structure of the chip based on the optimized circuit logic, including the positions and connections of each logic gate.
Routing Design: Engineers design the interconnecting wires within the circuit to ensure that signals can be transmitted effectively and meet timing and electrical specifications.
Physical Verification: The engineering team conducts various physical verification steps (such as DRC, LVS, and ERC) to check whether the layout and routing comply with manufacturing process rules.
Back-End Simulation: Engineers perform back-end simulations of the circuit to verify its functionality and performance under actual operating conditions.
GDSII Generation: The engineering team generates the final chip layout file in GDSII format, which contains precise graphical data for manufacturing.

Based on the GDSII file, the chip manufacturing facility may carry out photolithography, etching, deposition, packaging, and other manufacturing processes to produce the final chip product.

Before the IC chips are manufactured (or implemented), the placements, the floor plans, and the layout areas of the IC chips are first considered so as to determine a die size for each IC chip. In general, the die size will affect the manufacturing cost of the IC chip. Therefore, it is desirable to minimize the layout area of the IC chip.

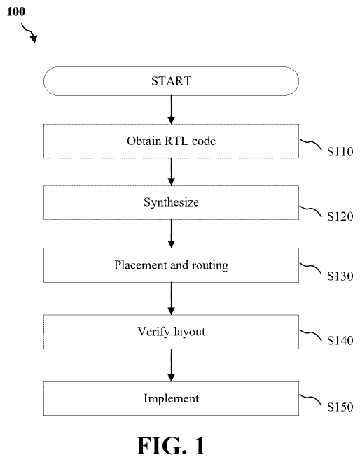

FIG. 1 illustrates a flow chart 100 illustrating a typical hierarchical design process of an integrated circuit (IC). First, in step S110, a register-transfer level (RTL) code describing the function performed by the IC is obtained. Next, in step S120, the RTL code is synthesized to generate gates for the IC. In general, the IC includes a plurality of blocks, and each block provides a significant function for the IC, such as a specific processor (e.g. an application processor, a video processor, an audio processor, or a controller), a memory (e.g. a SRAM module) and so on. Furthermore, each block has a corresponding RTL code, and then the RTL code of each block is synthesized to generate the gates of the block. Next, in step S130, a placement and routing procedure is performed to generate a layout of whole blocks within a chip area of the IC. For example, assuming that the IC includes N blocks, N placements of the N blocks will have been generated according to the RTL codes of the blocks, respectively. Thus, according to the N placements of the N blocks and the gates that do not belong to the N blocks, a chip placement and routing procedure is performed and a layout is obtained. In some embodiments, the layout is a whole chip layout. In some embodiments, the layout is a portion of a whole chip layout regarding some digital circuits of the IC. Next, an analysis procedure is performed and the layout is verified to check whether the layout violates any of the various constraints or rules (step S140). If there are no violations in the layout, the IC is fabricated (or implemented) according to the layout (step S150). If a violation is present in the layout, the layout of the IC must be modified to handle the violation until no violations are present.

In the analysis procedure, structural data such as parasitic resistance and capacitance values is obtained according to the layout. Furthermore, a post-layout simulation is performed to ensure proper functionality. Post-layout simulation is used to predict the IC's true performance, by rigorously testing the actual loading of the circuits and power-bus lines. According to the results obtained in the post-layout simulation, some problems can be uncovered such as excessive power-bus voltage drop (e.g. IR drop), which are generally not discoverable during RTL simulation.

IR (or voltage) drop generally refers to a difference in voltage from a supply voltage (e.g. VDD at a power node and is usually caused by the resistance (either due to parasitic resistance or due to other devices in the metal wire) present between a voltage source (providing the supply voltage) and the power node. Therefore, devices connected to nodes other than the power node may receive a terminal voltage, which is less than the supply voltage. If the terminal voltage is less than a permissible threshold voltage, the devices may not operate in a normal mode. For example, a circuit may become non-operational or operate at a lower frequency (compared to an optimal frequency). Accordingly, if the voltage drop exceeds a specific threshold voltage, an IR drop violation is present in the metal wire of the layout of the IC. Similarly, if the IR drop violation cannot be ignored, a correction is performed to address the IR drop violation. Furthermore, IR drop at each node of the layout and current flow on each path may be determined by performing a simulation. The determined values may be used to ensure that the design is in conformity with various IR drop requirements.

In the analysis procedure, after no IR drop violation that cannot be ignored is present, a design rule check (DRC) is performed on the layout to determine if there is a violation of the design rules associated with a given process. After the DRC successes, a layout-versus-schematic (LVS) is performed, so as to determine whether the layout corresponds to the original schematic, circuit diagram or RTL code of the IC design. As described above, after the layout is verified completely, a plurality of ICs are fabricated according to the layout.

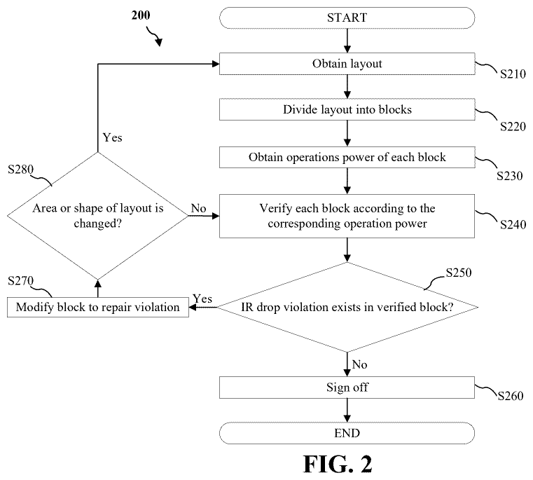

FIG. 2 illustrates a method 200 for analyzing IR drop of an IC. The method may be performed by a computing device such as a personal computer capable of operating an electronic design automation (EDA) tool. First, in step S210, a processor of the computer obtains a layout of the IC, and the layout can be displayed in a graphical user interface (GUI). Next, in step S220, the processor divides the layout into a plurality of blocks according to circuit function information of the IC, and each block corresponds to a significant function for the IC, such as a specific processor (e.g. an application processor, a video processor, an audio processor, or a controller), a memory (e.g. a SRAM module) and so on. Next, in step S230, the processor obtains information regarding a plurality of operation powers (voltages and currents) of the blocks and a plurality of operation temperatures of the blocks according to power-related information of the blocks. Each block has an individual operation power (voltage and current). In some embodiments, the individual operation power is determined according to the power consumption of the block. Next, the processor verifies each block with the individual operation power corresponding to the verified block (step S240), so as to check whether an IR drop violation exists in the verified block (step S250). In some embodiments, the blocks are verified simultaneously. In some embodiments, the blocks are verified in a specific order. If the IR drop violation exists in the verified block and the violation cannot be ignored, the processor modifies the block to repair the violation (step S270), and then the layout of the IC is changed. In some embodiments, the processor modifies the block in the layout, so as to increase the widths of the wires corresponding to the violation in the block. In some embodiments, the processor may increase the area of the layout or change the shape of the layout, so as to repair the violation. After the block has been modified and the area or shape of the layout has not been changed (S280), the modified block is verified again (step S240). If the area or shape of the layout is changed, the method is performed again from step S210. Conversely, if no IR drop violation exists in the verified block or the violation can be ignored, the layout is signed off (step S260) to perform subsequent procedures, such as DRC or LVS.

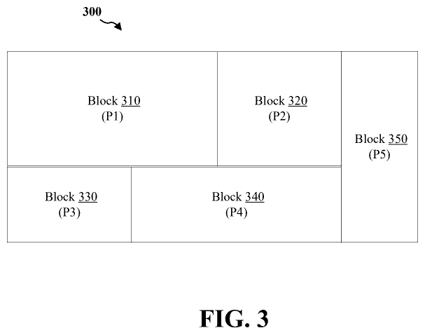

FIG. 3 is an example illustration of the layout 300 of an IC. After obtaining circuit function information of the IC, the layout 300 is divided into a plurality of blocks 310-350 (step S220). The blocks may be functional units such as logical functional units, sometimes referred to as “standard cells” in certain methodology of ID design. The power for operating these cells may be supplied from a power source which is intended to supply a rail voltage VDD at a rail to the standard cells. After obtaining power-related information of the blocks 310-350 of the IC 300, each operation power (voltage and current) is obtained for each of the blocks 310-350. For example, block 310 has a first operation power P1, block 320 has a second operation power P2, block 330 has a third operation power P3, block 340 has a fourth operation power P4, and block 350 has a fifth operation power P5. In some embodiments, the operation powers P1-P5 are the maximum operation powers for each block. In general, the maximum operation power is determined according to the number of gates in the block and the operation frequencies of the gates. Due to the number of gates and the operation frequencies of the gates being different from that of the other blocks, the operation powers of the blocks 310-350 may also be different. By verifying each block with the corresponding power, each wire of the block can be optimized, such as the width of each power wire having the smallest value, thereby each block of the layout can be minimized in terms of layout area.

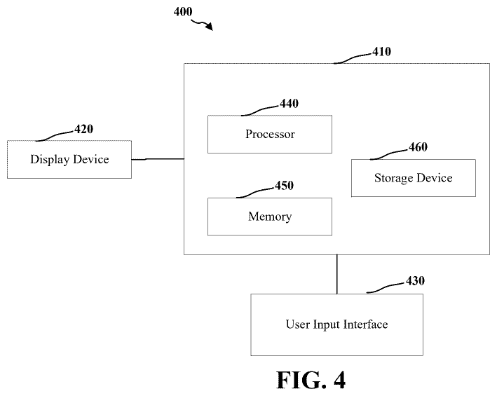

FIG. 4 is a block diagram 400 illustrating example physical components of a computer system. The computer system 400 includes a computer 410, a display device 420 and a user input interface 430. The computer 410 includes a processor 440, a memory 450, and a storage device 460. The computer 410 is coupled to the display device 420 and the user input interface 430. The computer 410 is capable of operating an electronic design automation (EDA) tool. Furthermore, the computer 410 is capable of receiving input instructions or information (e.g. circuit function information and power-related information) from the user input interface 430 and displaying the layout of the IC and the blocks of the layout on the display device 420. In one embodiment, the display device 420 is a GUI for the computer 410. Furthermore, the display device 420 and the user input interface 430 can be implemented in the computer 410. The user input interface 430 may be a keyboard, a mouse, and so on. In the computer 410, the storage device 460 can store the operating systems (OSs), applications, information (e.g. circuit function information and power-related information) and data that include input required by the applications and/or output generated by applications. The processor 440 of the computer 410 can perform one or more operations (either automatically or with user input) in any method that is implicitly or explicitly described in this disclosure. For example, during an operation, the processor 440 can load the applications of the storage device 460 into the memory 450, and then the applications can be used by the user to create, view, and/or edit a placement, a floor plan and a physical layout for a circuit design.

The data structures and code described in this disclosure can be partially or fully stored on a computer-readable storage medium and/or a hardware module and/or hardware apparatus. A computer-readable storage medium may be, but is not limited to, volatile memory, non-volatile memory, magnetic and optical storage devices such as disk drives, magnetic tape, CDs (compact discs), DVDs (digital versatile discs or digital video discs), or other media, now known or later developed, that are capable of storing code and/or data. Examples of hardware modules or apparatuses described in this disclosure include, but are not limited to, application-specific integrated circuits (ASICs), field-programmable gate arrays (FPGAs), dedicated or shared processors, and/or other hardware modules or apparatuses now known or later developed.

The methods and processes described in this disclosure can be partially or fully embodied as code and/or data stored in a computer-readable storage medium or device, so that when a computer system reads and executes the code and/or data, the computer system performs the associated methods and processes. The methods and processes can also be partially or fully embodied in hardware modules or apparatuses, so that when the hardware modules or apparatuses are activated, they perform the associated methods and processes. Note that the methods and processes can be embodied using a combination of code, data, and hardware modules or apparatuses.

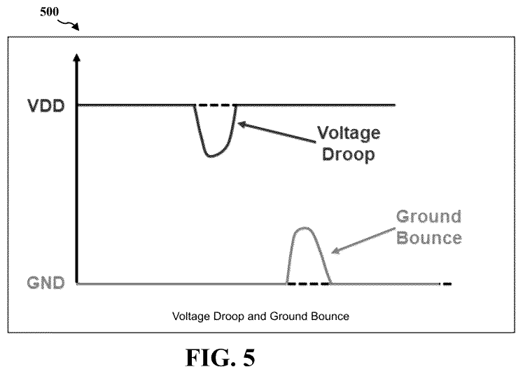

FIG. 5 is an example illustration 500 of voltage droop and ground bounce. During static timing analysis, the voltage (VDD) at all the devices is assumed to be a constant. Similarly, the ground pin (VSS) is assumed to be held at a constant 0 V. However, in reality, this voltage is not a constant and it varies with time. This variance in the voltage on the power and ground lines is referred to as Voltage droop and Ground bounce respectively, which are collectively referred to as Power noise. IR drop on the data path cells will impact setup-timing, while on the clock cells, it may cause both setup and hold timing problems.

Power supply fluctuation caused by IR drop can result in a significant impact to the timing and functionality of the IC. In general, a 10% fluctuation may translate to more than 10% timing uncertainty such that verification of the power supply integrity becomes a tape-out requirement in advance IC designs in order to ensure that the IC will function as designed.

The robustness of power grid needs to be tested thoroughly under various modes of operation. These various modes are referred to as Static IR Drop and Dynamic IR Drop. The static IR drop is primarily used to assess grid robustness, determining whether the grid can accommodate, for example, one watt of power consumption by the chip. Verification of whether the PG grid can support this power level is conducted through the static IR drop analysis. On the other hand, dynamic IR drop is highly design-specific. Depending on the functionality of the design, instances may toggle simultaneously or at different times, operating at various clock frequencies. Consequently, their current profiles can vary. This variability is inherently design-specific. As a result, groups of instances may begin to violate IR drop thresholds, which is indicative of dynamic IR drop. Notably, in the context of a chip, an “instance” typically refers to a specific occurrence or implementation of a hardware component, logic block, or functional unit within the chip's design. It can be understood as a single copy of a particular element that is instantiated within the chip's architecture to perform a specific task or set of tasks. For example, in a chip design, an instance might refer to: a single copy of a logic gate, such as an AND gate or an OR gate; a particular instantiation of a more complex functional block, like a processor core, memory controller, or input/output interface; or a specific configuration of a programmable logic element, such as a lookup table (LUT) or flip-flop, within a programmable logic device (PLD) or field-programmable gate array (FPGA).

Static IR drop takes into account the average current drawn from the power grid assuming average switching conditions. This analysis is performed early in the design cycle when simulation vectors are not quite available to the design teams. Instead, static IR drop relies on average data switching to compute the average current drawn from the power grid over 1 clock cycle.

Dynamic IR drop, also known as Instantaneous Voltage Drop (IVD), is the instantaneous drop in the voltage rails because of high transient current drawn from the power grid. Basically, IR drop refers to the voltage drop that occurs on the die due to parasitic and current consumption in the design. The current consumption, in turn, is dependent on the functionality of the design and varies across different designs. Dynamic IR drop takes into account the instantaneous current drawn from the power grid in a switching event. This analysis is usually performed towards the end of design cycle when design team has the simulation vectors available from their functional or test patter simulations. This mode of analysis is most time consuming, but nevertheless critical to ensure no surprises on silicon.

If the chip's operating frequency is not high, static IR drop verification may be adequate and its approach has been well studied and developed. The average supply current to each instance, including its loading current, short-circuit current, and leakage current, over several cycles is used to determine the full chip IR drop. Because the intrinsic decoupling capacitance existing in the chip between power and ground networks may provide enough current-spike filtering, the power and ground voltages stay within a small range around the values determined from the average current.

However, when operating frequency becomes higher or a group of nearby high-power cells switch simultaneously, the charge in the capacitors may be exhausted, causing severe power supply fluctuations. In this case, within-cycle transient analysis, including the consideration of power-ground RLC and intrinsic and inserted decoupling capacitors (i.e. DECAPs), is needed to determine the peak noise on the power-ground network. This analysis is defined as the dynamic IR analysis.

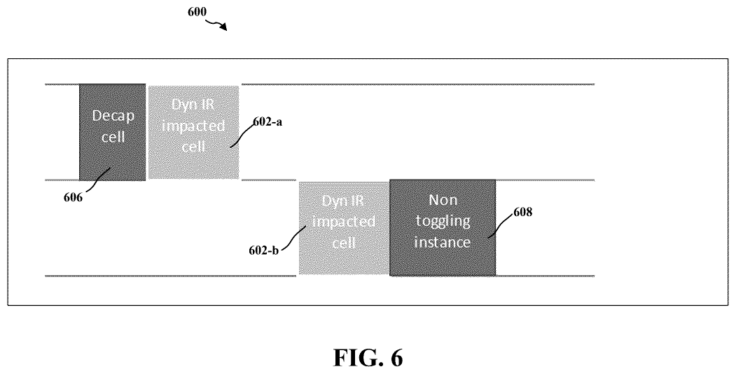

FIG. 6 is a diagram 600 illustrating an implementation addressing dynamic IR drop issues in integrated circuits. The diagram shows two primary approaches for managing dynamic IR drop: using DECAP cells 606 and utilizing non-toggling instances 608. A dynamic IR drop occurs when operating frequencies increase or when multiple high-power cells switch simultaneously, causing power supply fluctuations due to charge depletion in capacitors.

In modern integrated circuit designs, DECAP cells 606 function as local energy storage devices, similar to small batteries, that can store electrical charge and provide it to nearby dynamic IR impacted cells 602-a when needed. These DECAP cells 606 help maintain stable power delivery by supplying stored charge during periods of high current demand, thereby reducing voltage fluctuations in the power supply network.

The second approach involves utilizing non-toggling instances 608, which can provide supplementary charge to neighboring dynamic IR impacted cells 602-b through their intrinsic supply capacitance. A non-toggling instance refers to any digital logic cell, such as an AND gate or OR gate, that remains in a static state during specific operational modes while other cells are switching. When such a cell remains static, its intrinsic capacitance becomes available to support nearby cells experiencing dynamic IR issues. Further, changing the cell with an extra port may be equivalent to having a non-toggling cell near a Dynamic IR violation cell. This extra port with PMOS or NMOS in saturation connected to a dedicated net with stored charge serves the same purpose.

The dynamic IR drop challenge becomes particularly complex when dealing with clustered cells or varying toggle patterns based on different operational modes. Significant design modifications may be required late in the development cycle, including cell placement changes, re-floorplanning, or power grid (PG) enhancements. These modifications can lead to various design convergence issues, affecting both physical verification (PV) and static timing analysis (STA).

When dynamic IR drop impacts a specific cell, such as cells 602-a or 602-b, power grid may be enhanced by adding DECAP cells in proximity to the affected cells. The DECAP cells supply the necessary charge when the impacted cells require additional current. These DECAP cells can be either dedicated decoupling capacitor structures or repurposed non-toggling instances that provide similar functionality through their intrinsic capacitance.

The effectiveness of this solution depends on the available chip area near the impacted cells and the magnitude of the dynamic IR drop. The physical placement of DECAP cells must balance the need for adequate charge storage with layout constraints and timing requirements. Additionally, the intrinsic supply capacitance of non-toggling instances provides a complementary approach that can help mitigate dynamic IR issues without requiring additional dedicated decoupling capacitor cells.

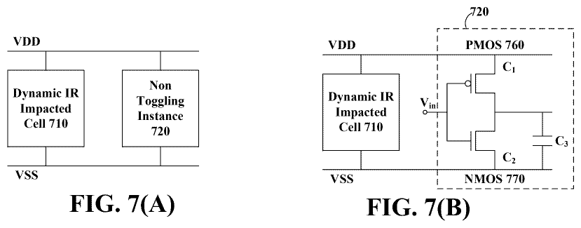

FIG. 7(A) is a diagram illustrating a simplified block representation of a Dynamic IR Impacted Cell 710 and a Non Toggling Instance 720 connected between a VDD power rail and a VSS ground rail. The Non Toggling Instance 720 demonstrates how a standard cell, when not switching states, can serve as a supplementary charge storage element similar to a decoupling capacitor cell for the Dynamic IR Impacted Cell 710. The dynamic IR impacted cell 710 experiences sudden power fluctuations due to transient current demands, leading to localized voltage drops known as dynamic IR drops. In contrast, the non-toggling instance 720 maintains a constant logic state for a given mode of operation and does not switch frequently.

The non-toggling instance 720 includes intrinsic capacitances between its power rails. When the non-toggling instance 720 remains static in a given logic state, it effectively functions as a small local reservoir of charge, similar to a decoupling capacitor cell 606. As a result, it helps provide additional localized charge to the nearby dynamic IR impacted cell 710 during periods of transient current demand, thereby reducing voltage droops that could otherwise cause timing or functional failures. This behavior is analogous to the behavior of the non-toggling instances 608 and the DECAP cells 606 discussed in relation to FIG. 6. A dynamic IR drop occurs when operating frequencies increase or when multiple high-power cells switch simultaneously, causing power supply fluctuations. A non-toggling instance, such as the Non Toggling Instance 720, can be any digital logic cell, such as an AND gate or OR gate, that remains in a static state during specific operational modes while other cells are switching.

FIG. 7(B) is a diagram illustrating a detailed transistor-level view inside the non-toggling instance 720. The non-toggling instance 720 is represented as an inverter stage including a PMOS 760 connected to the supply line VDD and an NMOS 770 connected to the ground line VSS. The intrinsic capacitances C₁, C₂, and C₃ are shown, with C₁ representing the intrinsic capacitance associated with the PMOS 760 to VDD, C₂ representing the intrinsic capacitance associated with the NMOS 770 to VSS, and C₃ representing the parasitic capacitance connected at the inverter's output node. These capacitances define how the non-toggling instance 720 can store charge depending on the logic state at its input node V_{¿}.

If V_{¿} is low, the PMOS 760 conducts strongly, pulling the output and its associated parasitic capacitance C₃ toward VDD and coupling C₃ with VDD through C1. Conversely, if V_{¿} is high, the NMOS 770 conducts strongly, pulling the output node and C₃ toward VSS and coupling C₃ and C₂ with VSS. As was discussed with respect to FIG. 6, this behavior is analogous to that of the DECAP cells 606, which serve as local energy storage devices, similar to small batteries. These DECAP cells help maintain stable power delivery by supplying stored charge during periods of high current demand, thereby reducing voltage fluctuations in the power supply network.

By setting the input to the non-toggling instance 720 to a fixed logic level, one can connect C3 either to the VDD rail through C1 or to the VSS rail with C2. The parasitic capacitance C₃ can be part of either the power or ground network, depending on the value at the gates of the PMOS 760 and NMOS 770. In both cases, the capacitance at the output node of the non-toggling instance 720 may be used to maintain more stable voltage levels for the neighboring dynamic IR impacted cell 710.

During a transient event where the dynamic IR impacted cell 710 draws a sudden surge of current, the non-toggling instance 720 can release stored charge from its intrinsic and parasitic capacitances, locally supplementing the power rail or ground reference node and lowering the effective transient voltage drop experienced by the impacted cell. This technique for mitigating dynamic IR issues does not rely solely on dedicated decoupling capacitor cells. By integrating a structure similar to a tie cell into any standard cell, such as an AND gate or OR gate, one could create a flexible source of stored charge. A dedicated net may be spread throughout the entire design, with multiple TIE-H or TIE-L cells belonging to the corresponding domain charging this net. This net may be a multi-driven net, providing a distributed charge reservoir across the design.

TIE-H and TIE-L cells are specialized standard cells used in integrated circuit design that serve to “tie” or connect a signal line to a fixed logic value. TIE-H (tie-high) cells connect a signal to a logical high value (1 or VDD), while TIE-L (tie-low) cells connect a signal to a logical low value (0 or ground/VSS). These cells essentially function as constant signal generators within the circuit design.

These cells can be used to charge a dedicated net that serves as a distributed charge reservoir throughout the design. The TIE-H cells, which may contain PMOS transistors that pass a logical high value efficiently, can be used to connect to and charge this dedicated net when addressing VDD-related dynamic IR drop issues. Similarly, TIE-L cells, which may contain NMOS transistors that pass a logical low value efficiently, can be used when addressing ground-related dynamic IR issues. These cells effectively become part of a domain-specific approach to managing dynamic IR drop.

When a given cell faces timing or performance issues due to transient IR drops, substituting it or pairing it with a cell that includes the described intrinsic and parasitic capacitances offers an alternative path to improve IR conditions. Avoiding large-scale placement changes or additional decoupling cells late in the design cycle leads to more stable designs and improved resilience against dynamic IR phenomena. This is important because, clustered cells or changes in toggle patterns can create dynamic IR drop issues that are difficult to fix late in the design cycle. Methods for mitigating dynamic IR drop, such as adding decoupling capacitor cells, have limitations, particularly in dense designs where space for such cells may be scarce. An alternative approach to address dynamic IR drop is to integrate charge storage capability directly into standard cells.

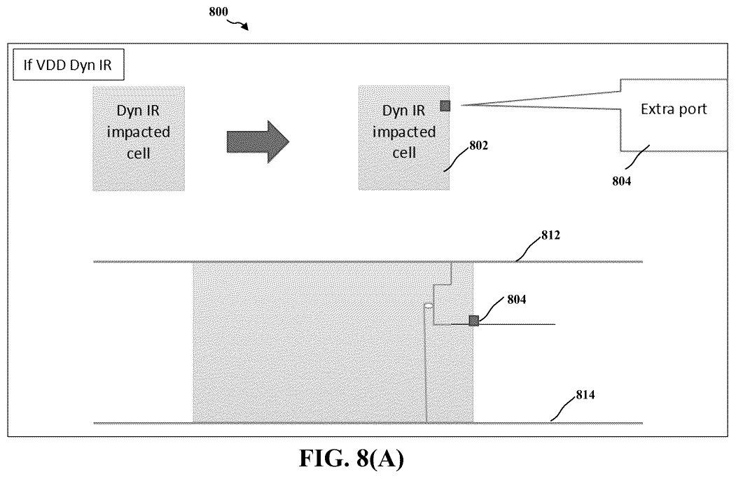

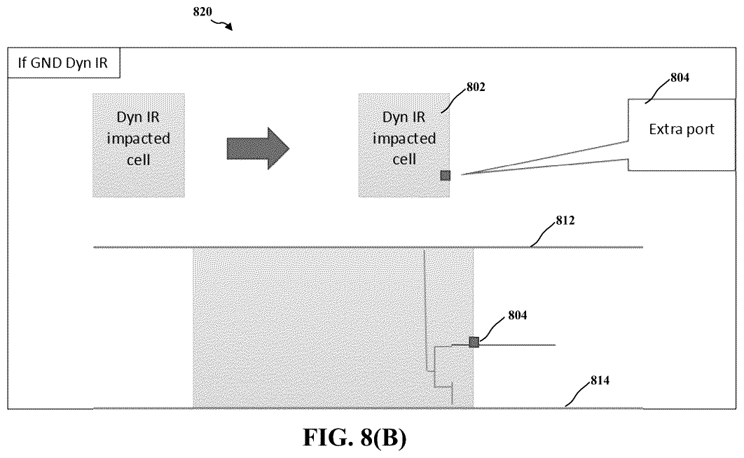

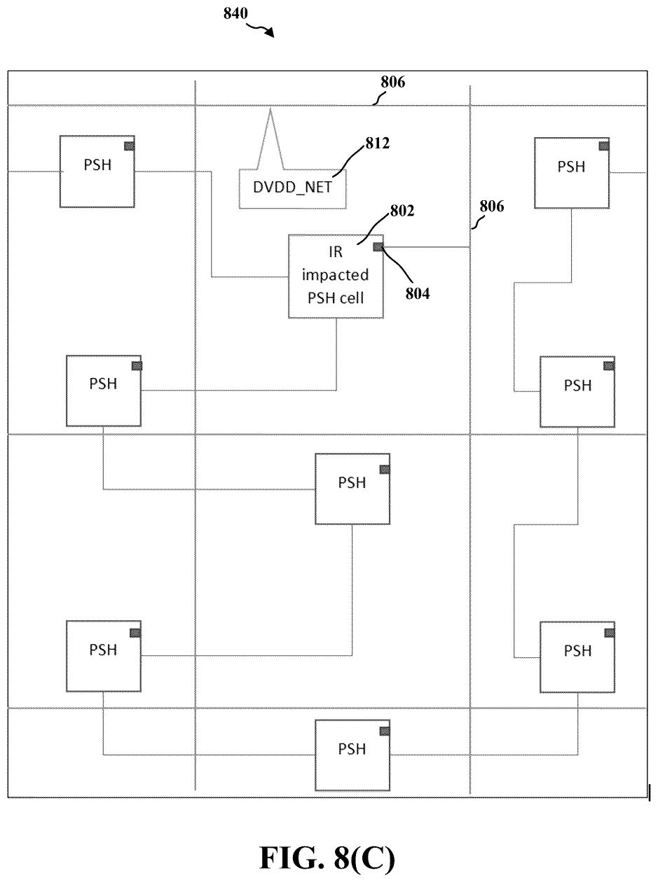

FIG. 8(A) and FIG. 8(B) illustrate an implementation aimed at addressing dynamic IR drop issues by integrating an additional port into a dynamic IR impacted cell. These figures expand upon the concepts introduced earlier, where a dynamic IR impacted cell can be modified to include one more port for selective connection to a specialized power or ground network. This approach reduces the need for significant physical design modifications late in the development cycle, such as adding dedicated decoupling capacitor cells or re-floorplanning, and avoids complications that may arise in physical verification or static timing analysis.

FIG. 8(A) is a diagram 800 illustrating a scenario in which the dynamic IR impacted cell 802 is vulnerable to supply voltage fluctuations on a VDD rail 812. Without remedial measures, transient events can cause localized voltage drops, potentially degrading performance or functionality. To counter this, the standard cell is replaced with a modified cell 802 that includes an additional port 804. This extra port 804 is connected through a PMOS transistor, whose gate is grounded, thereby forming an always-on path from an auxiliary power source to the cell 802. By doing so, the cell 802 can draw supplemental charge from a reserve network during periods of elevated current demand. This reserve network may represent a large on-chip capacitance or a separate supply domain dedicated to delivering charge as needed. The PMOS transistor can supply current efficiently to the cell when the main VDD 812 experiences transient IR drop. The result is an arrangement similar to placing a decoupling capacitor close to the cell, but implemented by adding a simple transistor-based port rather than an entirely separate cell. The reference line 814 indicates the ground (VSS) connection, which forms the return path. By adding this port 804 and incorporating an auxiliary net, a stable and temporary current supply path is available to mitigate timing and functional issues that often occur during dynamic IR drops.

The circuit operates as follows: during normal operation, the cell receives power through its standard VDD connection 812. When a dynamic IR drop occurs, causing the voltage at VDD 812 to temporarily decrease, the extra port 804 can supply additional current through the PMOS transistor to maintain proper voltage levels within the cell. This supplementary power delivery helps prevent timing violations and functional failures that would otherwise occur due to the voltage drop.

FIG. 8(B) is a diagram 820 illustrating a complementary configuration that addresses issues on the ground side. Instead of enhancing the cell's supply connection, the modification focuses on providing an alternate path to the ground rail 814. Here, the dynamic IR impacted cell 802 is similarly modified to include the extra port 804, but this port is connected through an NMOS transistor whose gate is driven high, thereby making it always-on. The cell 802 can access an additional ground reference point. If the local ground reference is compromised due to ground bounce or transient current surges, this alternate path to a stable auxiliary ground network reduces the effective IR drop. As a result, the cell 802 maintains a more stable ground potential, preventing timing violations and maintaining proper device operation.

The circuit operates as follows: during normal operation, the cell uses its standard ground connection 814. When a dynamic IR drop occurs in the ground network (which manifests as an unwanted voltage elevation above ground), the extra port 804 provides an additional path to ground through the always-on NMOS transistor. This helps maintain proper ground levels within the cell by providing a supplementary low-resistance path to ground.

The NMOS-based configuration effectively creates a parallel ground path-one through the cell's standard ground connection and another through port 804 via the NMOS transistor. When ground bounce or other ground-related dynamic IR issues occur, this parallel path helps maintain stable ground references within the cell, preventing timing violations and functional failures that could result from unstable ground connections. The separate ground network connected to port 804 acts as an additional ground sink, similar to how a decoupling capacitor would function but integrated directly into the cell structure through the NMOS switch arrangement.

Certain standard cells can store and release charge through their intrinsic parasitic capacitances. Non-toggling instances, when fixed at a particular logic state, are analogous to small on-chip reservoirs that can supply or absorb charge. Previously discussed components, such as the PMOS 760, the NMOS 770, and the intrinsic or parasitic capacitances C₁, C₂, and C₃, further show that standard logic cells may inherently include charge storage elements. These charge reservoirs can provide local current during transient events, much like dedicated decoupling capacitor cells, but are more easily integrated into the design without extensive physical changes.

By introducing an additional port 804, a dynamic IR impacted cell 802 can be swapped out late in the design flow with a counterpart cell that provides direct access to an auxiliary power or ground net. This feature accommodates design schedules and complexity, as it avoids large-scale grid enhancements or re-floorplanning. The method also supports both power and ground domains, enabling designers to handle localized IR drops on either rail. Moreover, since the rest of the standard cells remain unchanged and only specific cells connect to these auxiliary nets, the global design is less disrupted. The dedicated net connected to these extra ports needs to be spread throughout the entire design, with multiple TIE-H or TIE-L cells belonging to the corresponding domain charging this net, creating a multi-driven net that serves as a distributed charge reservoir.

FIG. 8(C) is a diagram 840 illustrating at an exemplary physical layout scenario where dynamic IR issues are mitigated by integrating an additional port into a dynamically IR impacted cell 802. In this figure, multiple standard cells, such as power supply hold (PSH) cells, are arranged within a domain of interconnected nets. Among these cells is an IR impacted PSH cell 802 that is connected to a specialized net 812, referred to as DVDD_NET, through an extra port 804. This additional port 804 is included within the cell 802 and can be selectively engaged to supply or sink charge depending on whether the cell requires supplementary support from a power or ground network. In the figure, the cell 802 is shown within a network including DVDD_NET 812 and routing lines 806, illustrating a placement scenario where localized charge reservoirs can be provided without large-scale design modifications.

The figure shows a domain-specific approach, where the dynamically IR impacted cell 802 may be replaced or swapped late in the design cycle with a cell that is functionally identical but includes the extra port 804. This extra port 804 is connected internally to a transistor structure, for instance a PMOS or NMOS transistor, configured so that the port 804 can provide an always-on path either to a dedicated power net or to a dedicated ground net. If the primary challenge involves a drop in the supply voltage rail, a PMOS transistor with its gate tied to ground can link the extra port 804 to a separate on-chip capacitance network acting like a power reservoir. Similarly, if the primary issue is related to ground bounce or raised ground reference levels, an NMOS transistor with its gate tied to a stable reference voltage can create a reliable ground return path through the extra port 804. By selecting the appropriate transistor type and connecting the extra port 804 to a specialized net 812 that is not part of the standard power grid, the IR impacted cell 802 gains a local charge source or sink that can mitigate transient voltage drops more effectively than conventional decoupling approaches.

This approach addresses the limitations of dedicating large areas for traditional DECAP cells, which might not be feasible in dense design regions. Instead of attempting to add or redistribute dedicated decoupling capacitors late in the design process, the existing standard cells are enhanced by integrating an additional port and connecting it to a separate net that includes a large charge storage capacity. Non-toggling instances in the vicinity, which include intrinsic capacitances such as C₁, C₂, and C₃ associated with the internal transistors like a PMOS 760 or an NMOS 770, can contribute to storing and supplying charge. These internal capacitances can effectively operate as local DECAP elements when set to a non-switching state, providing transient current to mitigate dynamic IR drops. The cell shown in FIG. 8(C) could be any type of cell, not just a PSH cell, and can be similarly adapted to include an extra port that is connected to a dedicated power or ground domain, or to a large on-chip capacitance structure representing a reserve charge supply.

As described, if a particular cell demonstrates performance issues such as timing violations or functional errors caused by localized voltage drops, the approach is to replace that cell with a variant that includes the additional port 804 and subsequently connect this port to the extra net 812. Since the rest of the design may remain unchanged, these modifications do not require a wholesale re-floorplanning or a reworking of the global power grid. Instead, they allow localized mitigation of dynamic IR problems. This flexibility is beneficial when addressing clustered violations or toggle pattern changes that arise in different operational modes late in the design cycle. By creating a domain-specific reservoir of charge through a dedicated net spread throughout the entire design and allowing an impacted cell to connect to it, dynamic IR drops can be alleviated effectively and predictably. This dedicated net is charged by multiple TIE-H or TIE-L cells belonging to the corresponding domain, making it a multi-driven net that provides a distributed charge reservoir.

As shown, a standard cell environment, such as a layout of PSH cells, can incorporate a dynamically IR impacted cell 802 that taps into a dedicated net 812 via an extra port 804. This connection provides immediate and localized charge supply or return paths, enabling stable operation without resorting to large-scale enhancements or design overhauls. The PMOS or NMOS structures integrated into this cell 802 help the cell access an auxiliary charge source or sink domain, effectively emulating a decoupling capacitor's role while remaining flexible and without requiring additional discrete DECAP cells. This integrated solution reduces transient voltage droops and supports stable timing and functionality.

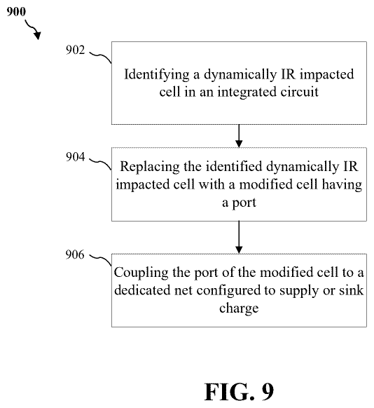

FIG. 9 illustrates a flow chart 900 of a process for mitigating dynamic IR. The process may be implemented by one or more computing device. At block 902, the process includes: identifying a dynamically IR impacted cell in an integrated circuit.

Subsequently, at block 904, the process includes: replacing the identified dynamically IR impacted cell with a modified cell having a port.

Thereafter, at block 906, the process includes: coupling the port of the modified cell to a dedicated net configured to supply or sink charge.

In certain configurations, coupling the port may include: coupling the port to the dedicated net through a PMOS transistor when the dynamically IR impacted cell experiences voltage drop issues.

In certain configurations, the PMOS transistor may be configured in an always-on state by coupling a gate of the PMOS transistor to ground.

In certain configurations, coupling the port may include: coupling the port to the dedicated net through an NMOS transistor when the dynamically IR impacted cell experiences ground bounce issues.

In certain configurations, the NMOS transistor may be configured in an always-on state by coupling a gate of the NMOS transistor to a power supply voltage.

In certain configurations, the process may further include: creating the dedicated net as a separate network from a primary power grid of the integrated circuit.

In certain configurations, the dedicated net may include a charge storage network configured to function as a decoupling capacitor.

In certain configurations, the dedicated net may be spread throughout the integrated circuit and may be charged by multiple TIE-H or TIE-L cells belonging to a corresponding domain.

In certain configurations, the dedicated net may be a multi-driven net.

In certain configurations, replacing the identified dynamically IR impacted cell may include: maintaining identical functionality between the modified cell and the identified dynamically IR impacted cell while adding the port.

In certain configurations, identifying the dynamically IR impacted cell may include: detecting timing violations or functional failures due to voltage fluctuations in the integrated circuit.

In certain configurations, the process may further include: implementing the modified cell without requiring placement changes or re-floorplanning of surrounding cells in the integrated circuit.

In certain configurations, the modified cell may include a standard logic cell selected from the group consisting of an AND gate, an OR gate, and an inverter.

In certain configurations, the dedicated net may be a domain-specific network separate from primary power and ground networks of the integrated circuit.

In certain configurations, the process may further include: maintaining the port disconnected from the dedicated net for other cells in the integrated circuit that do not experience dynamic IR issues.

In another aspect, the present disclosure also provides an integrated circuit. The integrated circuit includes a dedicated net; a modified standard cell including a port; a transistor coupled between the port and the dedicated net. The dedicated net is configured as a charge storage network that supplies or sinks charge to mitigate dynamic IR drop within the modified standard cell.

In certain configurations, the transistor may be a PMOS transistor having a gate coupled to ground. The PMOS transistor may be configured to be always-on, thereby providing a continuous conductive path from the dedicated net to the modified standard cell when supply voltage transient drops occur.

In certain configurations, the transistor may be an NMOS transistor having a gate coupled to a supply voltage rail. The NMOS transistor may be configured to be always-on, thereby providing a continuous conductive path from the modified standard cell to the dedicated net for mitigating ground bounce or transient ground voltage elevations.

In certain configurations, the dedicated net may be spread throughout the integrated circuit and may be charged by multiple TIE-H or TIE-L cells belonging to a corresponding domain.

In certain configurations, the dedicated net may be separate from a primary power grid and may be configured to provide localized charge storage without requiring placement of dedicated decoupling capacitor cells in dense circuit regions.

It is understood that the specific order or hierarchy of blocks in the processes/flowcharts disclosed is an illustration of exemplary approaches. Based upon design preferences, it is understood that the specific order or hierarchy of blocks in the processes/flowcharts may be rearranged. Further, some blocks may be combined or omitted. The accompanying method claims present elements of the various blocks in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more. ” The word “exemplary” is used herein to mean “serving as an example, instance, or illustration. ” Any aspect described herein as “exemplary” is not necessarily to be construed as preferred or advantageous over other aspects. Unless specifically stated otherwise, the term “some” refers to one or more. Combinations such as “at least one of A, B, or C,” “one or more of A, B, or C,” “at least one of A, B, and C,” “one or more of A, B, and C,” and “A, B, C, or any combination thereof” include any combination of A, B, and/or C, and may include multiples of A, multiples of B, or multiples of C. Specifically, combinations such as “at least one of A, B, or C,” “one or more of A, B, or C,” “at least one of A, B, and C,” “one or more of A, B, and C,” and “A, B, C, or any combination thereof” may be A only, B only, C only, A and B, A and C, B and C, or A and B and C, where any such combinations may contain one or more member or members of A, B, or C. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. The words “module,” “mechanism,” “element,” “device,” and the like may not be a substitute for the word “means. ” As such, no claim element is to be construed as a means plus function unless the element is expressly recited using the phrase “means for. ”

What is claimed is:

1. A method, comprising:
identifying a dynamically IR impacted cell in an integrated circuit;
replacing the identified dynamically IR impacted cell with a modified cell having a port; and
coupling the port of the modified cell to a dedicated net configured to supply or sink charge.

2. The method of claim 1, wherein coupling the port comprises:
coupling the port to the dedicated net through a PMOS transistor when the dynamically IR impacted cell experiences voltage drop issues.

3. The method of claim 2, wherein the PMOS transistor is configured in an always-on state by coupling a gate of the PMOS transistor to ground.

4. The method of claim 1, wherein coupling the port comprises:
coupling the port to the dedicated net through an NMOS transistor when the dynamically IR impacted cell experiences ground bounce issues.

5. The method of claim 4, wherein the NMOS transistor is configured in an always-on state by coupling a gate of the NMOS transistor to a power supply voltage.

6. The method of claim 1, further comprising:
creating the dedicated net as a separate network from a primary power grid of the integrated circuit.

7. The method of claim 1, wherein the dedicated net comprises a charge storage network configured to function as a decoupling capacitor.

8. The method of claim 1, wherein the dedicated net is spread throughout the integrated circuit and is charged by multiple TIE-H or TIE-L cells belonging to a corresponding domain.

9. The method of claim 8, wherein the dedicated net is a multi-driven net.

10. The method of claim 1, wherein replacing the identified dynamically IR impacted cell comprises:
maintaining identical functionality between the modified cell and the identified dynamically IR impacted cell while adding the port.

11. The method of claim 1, wherein identifying the dynamically IR impacted cell comprises:
detecting timing violations or functional failures due to voltage fluctuations in the integrated circuit.

12. The method of claim 1, further comprising:
implementing the modified cell without requiring placement changes or re-floorplanning of surrounding cells in the integrated circuit.

13. The method of claim 1, wherein the modified cell comprises a standard logic cell selected from the group consisting of an AND gate, an OR gate, and an inverter.

14. The method of claim 1, wherein the dedicated net is a domain-specific network separate from primary power and ground networks of the integrated circuit.

15. The method of claim 1, further comprising:
maintaining the port disconnected from the dedicated net for other cells in the integrated circuit that do not experience dynamic IR issues.

16. An integrated circuit, comprising:
a dedicated net;
a modified standard cell, including:
a port;
a transistor coupled between the port and the dedicated net, wherein the dedicated net is configured as a charge storage network that supplies or sinks charge to mitigate dynamic IR drop within the modified standard cell.

17. The integrated circuit of claim 16, wherein the transistor is a PMOS transistor having a gate coupled to ground, the PMOS transistor configured to be always-on, thereby providing a continuous conductive path from the dedicated net to the modified standard cell when supply voltage transient drops occur.

18. The integrated circuit of claim 16, wherein the transistor is an NMOS transistor having a gate coupled to a supply voltage rail, the NMOS transistor configured to be always-on, thereby providing a continuous conductive path from the modified standard cell to the dedicated net for mitigating ground bounce or transient ground voltage elevations.

19. The integrated circuit of claim 16, wherein the dedicated net is spread throughout the integrated circuit and is charged by multiple TIE-H or TIE-L cells belonging to a corresponding domain.

20. The integrated circuit of claim 16, wherein the dedicated net is separate from a primary power grid and is configured to provide localized charge storage without requiring placement of dedicated decoupling capacitor cells in dense circuit regions.
